(19) United States
(12) Patent Application Publication
(10) Pub. No.: US 2025/0133654 A1
(43) Pub. Date: Apr. 24, 2025

(54) PRINTED CIRCUIT BOARD DIELECTRIC MOLDING, MACHINING AND WIRE INSERTION

(71) Applicant: INFINITUM ELECTRIC INC., Round Rock, TX (US)

(72) Inventors: Edward C. CARIGNAN, Round Rock, TX (US); Paulo GUEDES-PINTO, Round Rock, TX (US)

(73) Assignee: INFINITUM ELECTRIC INC., Round Rock, TX (US)

(21) Appl. No.: 19/005,153

(22) Filed: Dec. 30, 2024

Related U.S. Application Data
(63) Continuation-in-part of application No. 18/617,391, filed on Mar. 26, 2024.
Application No. 18/617,391 is a continuation-in-part of application No. 18/382,921, filed on Oct. 23, 2023, now Pat. No. 12,219,698.
Application No. 18/382,921 is a continuation of application No. 18/127,453, filed on Mar. 28, 2023, now Pat. No. 11,800,640.

(51) Int. Cl. H05K 1/02; H02K 3/26; H05K 1/03; H05K 3/18

(52) U.S. Cl. CPC H05K 1/0284; H02K 3/26; H05K 1/0366; H05K 3/18; H05K 2201/09036

(57) ABSTRACT

A printed circuit board (PCB) has a dielectric substrate of fiber-reinforced polymer with opposite sides. Each side has channels formed by molding or machining the dielectric substrate. Conductive wires are inserted into the channels to define conductive traces.

### CROSS-REFERENCE TO RELATED APPLICATION

This application is a continuation-in-part of and claims priority to and the benefit of U.S. patent application Ser. No. 18/617,391, filed Mar. 26, 2024 (docket 85245-1705), which is a continuation-in-part of and claims priority to and the benefit of U.S. patent application Ser. No. 18/382,921, filed Oct. 23, 2023 (docket 85245-1703), which is a continuation of and claims priority to and the benefit of U.S. patent application Ser. No. 18/127,453, filed Mar. 28, 2023 (now U.S. Pat. No. 11,800,640; docket 85245-1700), each of which is incorporated herein by reference in its entirety.

### BACKGROUND OF THE INVENTION

### Field of the Disclosure

The present disclosure relates in general to an additive system, method and apparatus for printed circuit board (PCB) construction, in particular, where PCB traces are designed to carry large electrical currents, and further relates to PCB structures designed to operate as stators in electric motors.

### Description of the Prior Art

A PCB typically can comprise one or more layers of a foil made of copper or another electrically conductive material, such as aluminum. The foil is laminated onto a sheet of a dielectric material made of a fiber-reinforced polymer, such as a NEMA FR-4 woven fiberglass cloth with epoxy resin binder laminate. The electrically conductive layer is laminated on one or both sides of the dielectric (e.g., FR-4) sheet. The most common conductive material used in PCB construction is copper foil, which can have electrical conductivity of 58 mS/m at 20° C., and its thickness is expressed in ounces of copper per square foot, being 1 oz/ft² copper the most common copper foil employed in PCB construction. The 1 oz/ft² copper foil has a thickness of about 35 μm. The PCB can have a plurality of conductive pads that are interconnected by a plurality of traces. Both pads and traces can be formed by etching the conductive material through a conventional photo-lithography process 100 depicted in FIG. 1, which includes steps 101-129.

In some embodiments, portions of a circuit formed in the PCB can carry high electric currents (e.g., several to tens of amperes). In those cases, the PCB can be made of thicker conductive foil. The commonly commercially available copper foils for PCBs are 2, 3 and 4 oz/ft², which have thicknesses of 70, 105 and 140 μm, respectively. In other embodiments, in addition to employing thicker foil, the PCB can have multiple layers configured to receive high electric currents that can flow in parallel layers and/or parallel traces. Examples of PCB structures that require high electric current carrying capability are PCB stators employed in axial field rotary energy devices similar to the devices described in U.S. Pat. Nos. 10,141,803, 10,135,310, 10,340,760, 10,141,804, 10,186,922, and 11,502,583, each of which is incorporated herein by reference in its entirety. Some of these PCB stator embodiments can have a plurality of conductive layers and conductive traces configured to carry high electric currents, as shown in FIG. 2, which shows a partial sectional view of a PCB structure 200 with a plurality of traces 201.

The conventional PCB manufacturing process depicted in FIG. 1 presents some disadvantages. First, the etching step 105 of the process 100 does not produce traces with a uniform cross section. FIG. 3 shows a magnified view of two conventional, adjacent traces 201 after the etching step 105 (FIG. 1). In FIG. 3, the width A of the base of the trace is wider than the width B at the top of the trace. The distance between adjacent traces C has a minimum value, called space, based on the voltage applied to the PCB. While the distance C can meet the minimum space requirement, the distance D at the top of the trace exceeds the minimum clearance value. The tapered profile at the side walls of the trace are controlled to some extent by adjusting etching parameters. However it may be difficult to eliminate in its entirety. In PCB manufacturing, an “etch factor” is defined as the ratio W/T where W=(A−B)/2 and T is the thickness of the conductive trace. This etch factor is typically between 0.3 and 0.5. The result of the etching process is that the volume 202, which is the difference between a maximum theoretical rectangular trace shown as a dotted line and the actual trace cross section, is lost resulting in a smaller cross section available to current carrying, which can lead to higher resistance and a less efficient electrical circuit.

A second disadvantage of the conventional PCB manufacturing process 100 depicted in FIG. 1 is that, in some steps of the process, such as step 101 (pre-clean), step 108 (oxide coat), and step 111 (through hole metallization) for example, some conductive material can be removed, resulting in further reduction of the sectional area of traces 201.

A third disadvantage of the conventional PCB manufacturing process 100 depicted in FIG. 1 is that conductive material is removed from the PCB conductive layers. Although most of the conductive material can be recovered, the chemical processes required to recover conductive material employ hazardous chemicals and are energy intensive.

Finally, some PCB structures, particularly the PCB stators mentioned previously, require multiple layers of conductive material, so steps 101 to 119 must be repeated several times and the resulting laminates must be stacked together forming a multiple layer structure as shown in FIG. 2. In the conventional multiple layer PCB structure 200 shown in FIG. 2, it can be seen that dielectric layers 205, typically comprising a B-stage glass epoxy laminate such as a NEMA FR-4 prepreg, are stacked between some conductive layers formed by traces 201. The main purpose of layers 205 is to bond conductive layers together and fill the spaces 206 between adjacent traces 201. These layers 205 add to the overall thickness of the PCB structure hindering thermal dissipation, because they are usually poor thermal conductors.

Additive methods to manufacture PCB structures have been proposed in the past with different shortcomings. U.S. Pat. No. 6,426,241 proposes a method where channels and pockets in a tridimensional (3D) dielectric substrate are filled with a molten conductive material. That process requires a conductive material with a low melting point, such as tin-based solder alloys, for example, which makes the method unsuitable for high current applications (e.g., several to tens of amperes) as the typical conductivity of solder alloys is 10 times lower than copper. Furthermore, that process allows for filling channels and pockets on only one side of a 3D dielectric substrate.

U.S. Pat. Nos. 8,240,036 and 9,332,650 teach a method where channels and pockets are formed on a dielectric substrate with a swellable resin film. That process requires the conductive material to be deposited through electroless plating, which limits the thickness of the conductive material to 2.5 μm or less. That makes it unsuitable for high current applications (e.g., several to tens of amperes) where the conductive material thickness can be 105 μm or more. Furthermore, that method allows for creating channels and pockets on only one side of a 3D dielectric substrate.

JP2004281427 proposes a method of forming a 3D conductive structure where a conductive material is deposited by electroless plating on some surfaces of a channel in a 3D dielectric structure. That method also is unsuitable for high current applications (e.g., several to tens of amperes) because the thickness of the conductive material is limited to 2.5 μm or less.

U.S. Pat. No. 9,072,187 teaches a method of forming a 3D conductive structure on a 3D dielectric substrate with channels with different depths where conductive lines (or traces) are offset from each other. This solution also is unsuitable for high current applications (e.g., several to tens of amperes) because it does not use the full depth of some channels to form conductive traces, therefore not minimizing the resistance of the conductive traces.

US2020/0313526 teaches a method of forming a 3D conductive structure for an armature for use in an axial flux machine where a robot lays a conductive wire on a tacky substrate. The disadvantage of this method is that the bond between the tacky substrate and the conductive wire is limited to a small contact area between them, which does not provide sufficient anchoring nor the lap shear strength required during operation of an axial flux machine. This is particularly true during torque transients that enable movement of the conductive wire, which can jeopardize the integrity of the armature. Based on those previously disclosed solutions, improvements in PCB manufacturing continue to be of interest, particularly for circuits intended to carry high currents.

### SUMMARY OF THE INVENTION

Embodiments of PCBs and molding and electrolytic metallization processes for PCBs are disclosed. For example, a product and process for manufacturing PCB structures whereby a dielectric material made of a fiber-reinforced polymer is configured into a dielectric substrate with channels and pockets that can be filled with a conductive material, such as copper by electrolytic metallization, for example. This can form conductive layers with a specific thickness according to the requirements of the PCB design, such as 140 μm or more, for example. Note that this solution is not restricted by the commercial availability of conductive foils, such as 1, 2, 3 or 4 oz/ft² copper foil. After the conductive material is deposited on the dielectric substrate by electrolytic metallization, for example, it can be laminated into a multiple layer PCB structure as required by the PCB design.

In addition, some embodiments enable the use of only the amount of conductive material necessary to form the conductive layers of the PCB structure with minimum waste or need to recover excess material. PCB structures can have one or more conductive layers. Hereinafter, a conductive layer with its respective dielectric substrate or a dielectric substrate with conductive layers on both sides will be referred to as a “PCB panel” or simply “panel”.

### BRIEF DESCRIPTION OF THE DRAWINGS

FIG. 1 is a process flow chart for a conventional PCB manufacturing process.

FIG. 2 is a sectional view of a conventional PCB structure with multiple layers.

FIG. 3 is an enlarged sectional view of a portion of the conventional PCB structure shown in FIG. 2.

FIG. 4 is a process flow chart of an embodiment of a process for manufacturing a PCB structure using molded and plated 3D dielectric substrates.

FIG. 5A is a perspective view of an embodiment of a top side of a 3D dielectric substrate.

FIG. 5B is a perspective view of an embodiment of a bottom side of a 3D dielectric substrate.

FIG. 6A is a perspective view of an embodiment of a mold to form a two-sided 3D dielectric substrate, and is shown before mold closure.

FIG. 6B is a sectional perspective view of an embodiment of the mold depicted in FIG. 6A, taken along the line A-A of FIG. 6A, and is shown closed.

FIG. 6C is a side view of an alternate embodiment of a portion of the mold depicted in FIGS. 6A and 6B.

FIG. 7A is a perspective view of an embodiment of a PCB panel showing the top and bottom sides.

FIG. 7B is a sectional side view of an embodiment of the PCB panel shown in FIG. 7A, taken along the line A-A in FIG. 7A.

FIG. 7C is a sectional side view of an alternate embodiment of a PCB panel.

FIG. 8 is a sectional side view of an embodiment of a multi-layer PCB structure.

FIG. 9 is a sectional side view of another embodiment of a multi-layer PCB structure.

FIG. 10A is a perspective view of an embodiment of a 3D dielectric substrate showing the top and bottom sides.

FIG. 10B is a sectional view of an embodiment of the 3D dielectric substrate shown in FIG. 10A, taken along the line A-A in FIG. 10A.

FIG. 11A is a perspective view of an embodiment of a PCB panel showing the top and bottom sides.

FIG. 11B is a sectional view of an embodiment of the PCB panel shown in FIG. 11A, taken along the line A-A in FIG. 11A.

FIG. 12 is a partial top view of an embodiment of a PCB stator.

FIG. 13 is a top view of an embodiment of a coil for a PCB stator, as noted in FIG. 12.

FIG. 14 is a sectional side view of an embodiment of a PCB stator coil, taken along the line A-A of FIG. 13.

FIG. 15 is a sectional side view of another embodiment of a PCB stator.

FIG. 16 is a process flow chart of an embodiment of an alternate process to manufacture a PCB stator.

FIG. 17A is a top view of a PCB stator built according to the process shown in FIG. 16.

FIG. 17B is a partial isometric view of an embodiment of a PCB stator panel.

FIG. 17C is a sectional view of the PCB stator panel shown in FIG. 17B, taken along the line B-B.

FIGS. 17D-17M are sectional views of various embodiments of channels and wires in a PCB stator panel.

FIGS. 18A-18B are sectional views of embodiments of PCB stators.

FIGS. 19A-19C are schematic views of embodiments of conductive wires connected to vias.

### DETAILED DESCRIPTION OF THE INVENTION

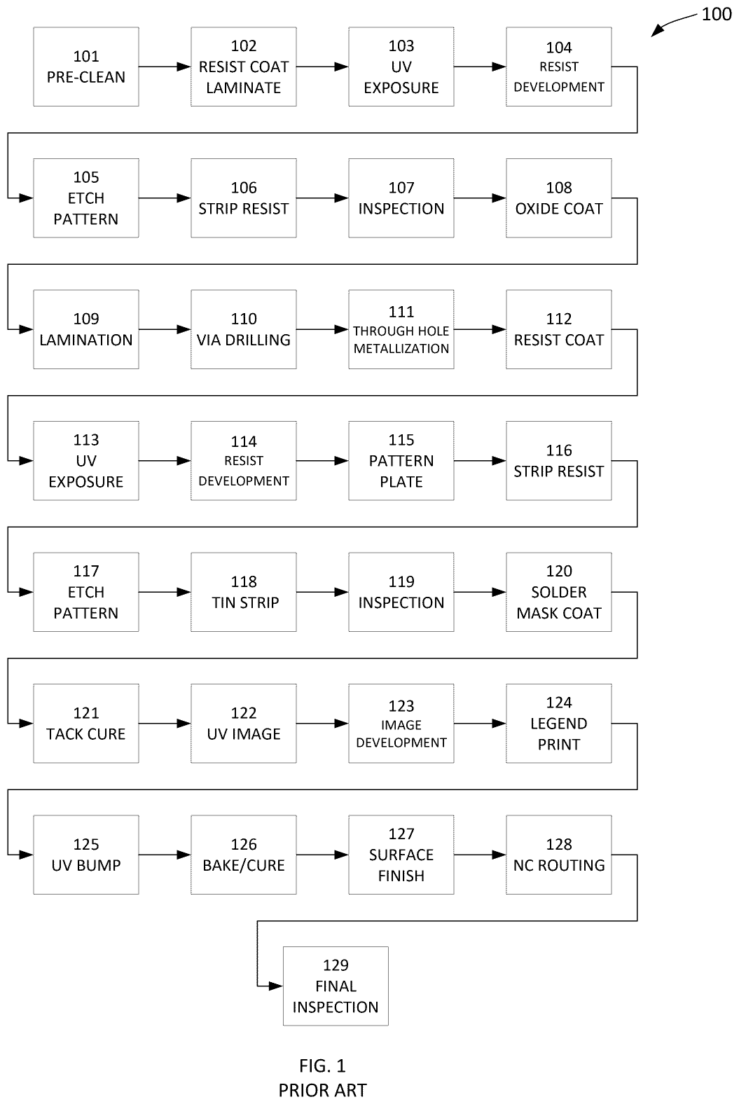

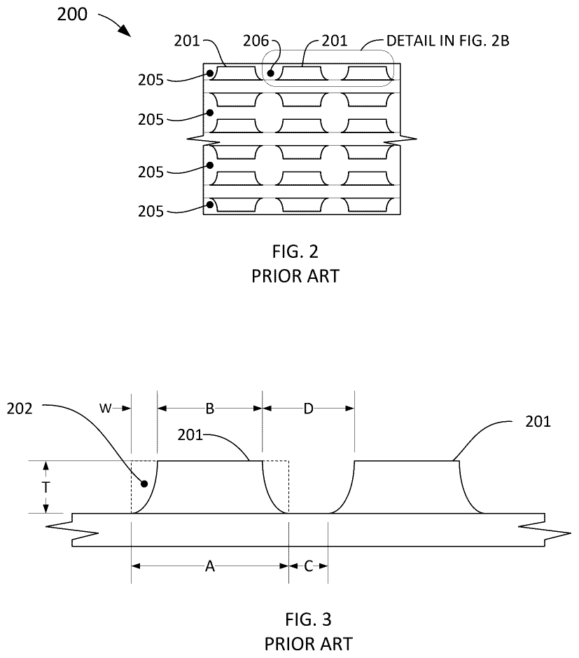

Referring to FIGS. 1-19, embodiments of a printed circuit board (PCB) can be built for several purposes including those that require high current circuits (e.g.: several to tens of amperes), such as DC/DC, DC/AC, AC/DC or AC/AC power converters. AC/AC converters can be used to convert AC power, typically provided at frequencies such as 60 or 50 Hz, to AC power at a frequency suitable to operate an electric motor, for example. Other PCB structures can be configured to operate as a stator for an axial field rotary energy device, which can be similar to the devices described in U.S. Pat. Nos. 10,141,803, 10,135,310, 10,340,760, 10,141,804, 10,186,922 and 11,502,583, each of which is incorporated herein by reference in its entirety.

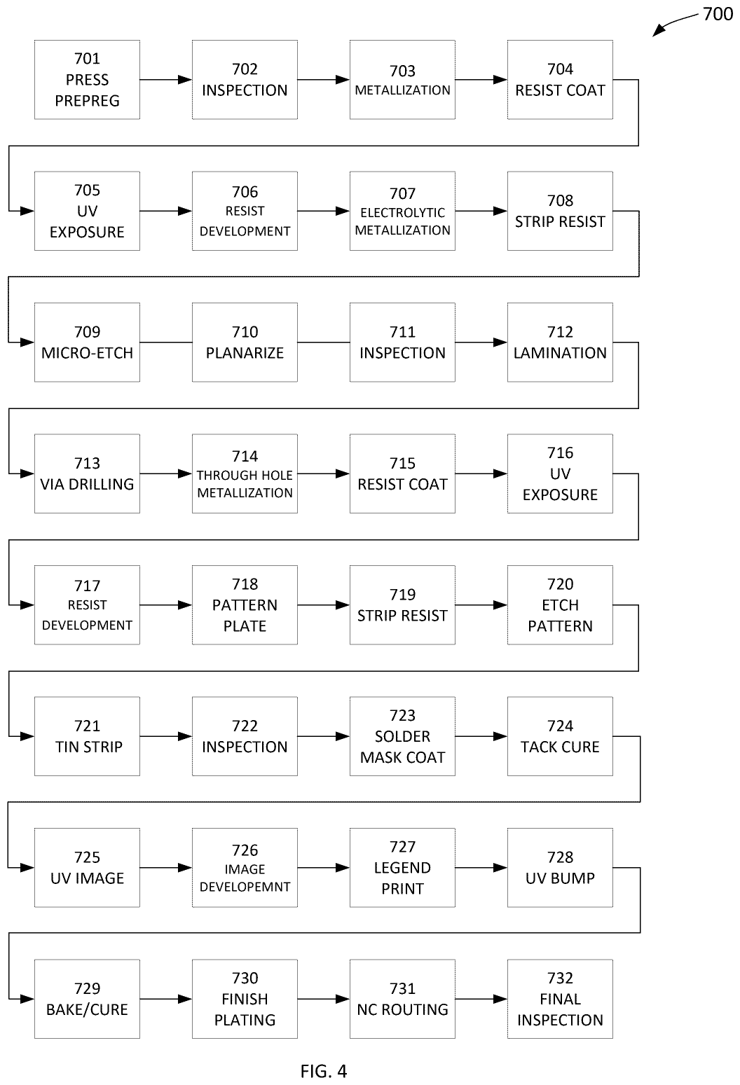

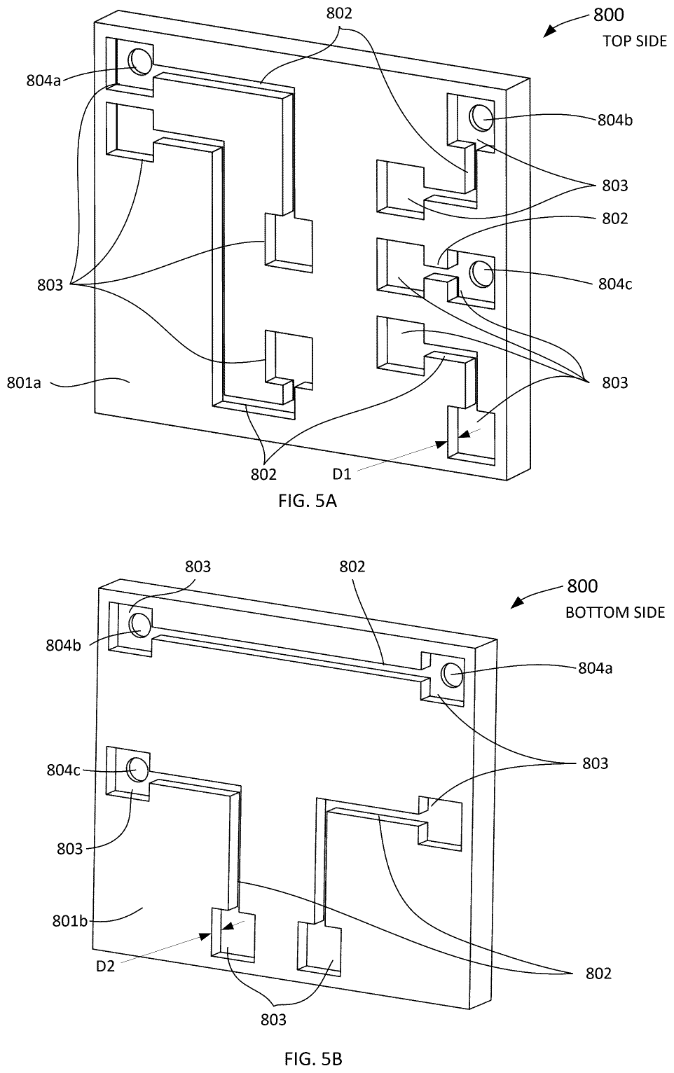

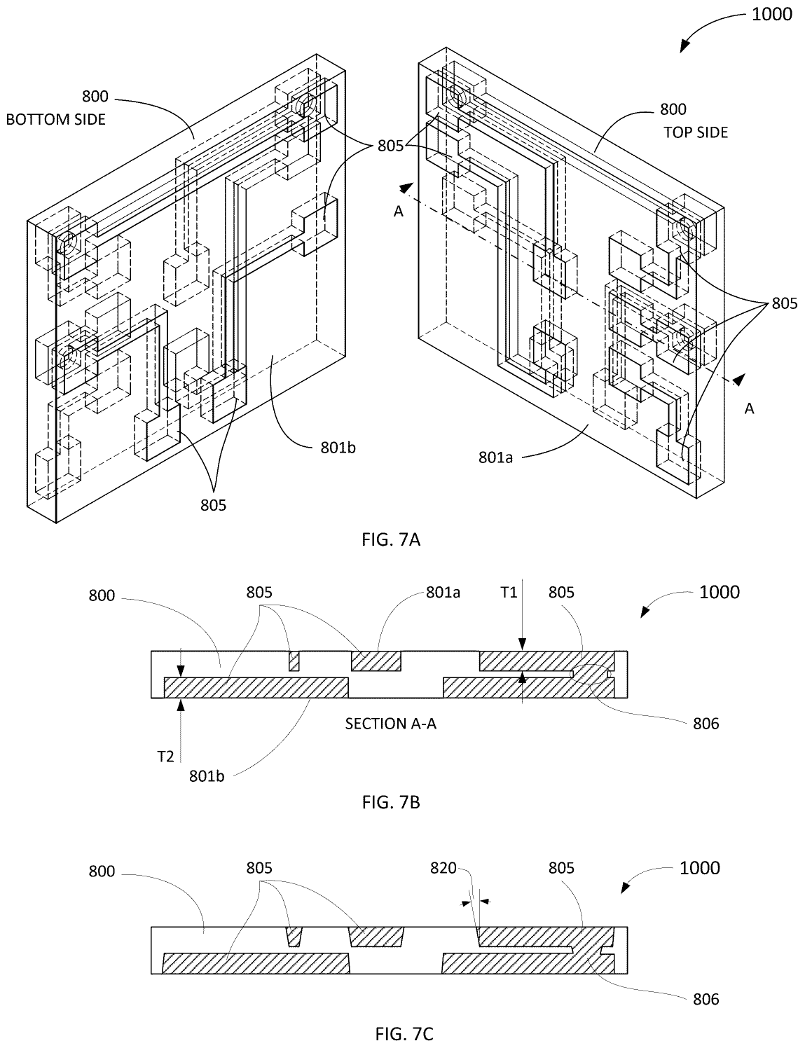

An embodiment of a PCB manufacturing process 700 is described in FIG. 4, where in step 701, a B-stage dielectric material made of a fiber-reinforced polymer, such as NEMA FR-4 glass epoxy laminate, for example, is molded to form a three-dimensional (3D) dielectric substrate 800 as shown in FIGS. 5A and 5B. The 3D dielectric substrate 800 comprises a first side 801a and a second side 801b opposite to side 801a, and sides 801a and 801b can be substantially flat and parallel to each other. The side 801a can have a layout of channels 802 and pockets 803, hereinafter referred to as “top side”, with a depth “D1” (FIG. 5A) that is the same or substantially the same as the thickness “T1” (FIG. 7B) of the conductive traces and pads of the PCB panel 1000. The side 801b can have a layout of channels 802 and pockets 803, hereinafter referred to as “bottom side”, with a depth “D2” (FIG. 5B) that is the same or substantially the same as the thickness “T2” (FIG. 7B) of the conductive traces and pads of the PCB panel. In some embodiments the depths “D1” and “D2”, and corresponding thicknesses “T1” and “T2”, can be the same or within 25 μm of each other, for example, and in others “D1” and “D2” can be different. Although FIGS. 5A and 5B depict an embodiment of a 3D dielectric substrate 800 with two sides (e.g., top and bottom sides) and each side has a different layout, it should be understood that other embodiments of the 3D dielectric substrate 800 can have two sides with identical layouts, and others may have only one side.

In addition, the 3D dielectric substrate 800 can have openings 804a, 804b and 804c, hereinafter collectively referred to as “openings 804”, to connect the two sides of the 3D dielectric substrate 800. In addition to a NEMA FR-4 glass epoxy laminate, the 3D dielectric substrate 800 can also be formed from other fiber-reinforced polymers, such as a glass-reinforced polyimide laminate, or ceramic-reinforced polytetrafluorethylene resin based laminate, for example, to impart mechanical rigidity to the 3D dielectric substrate. While the 3D dielectric substrate 800 shown in FIGS. 5A and 5B has three openings 804a-c to connect its two sides, other embodiments can have a different number of openings 804, or no openings at all.

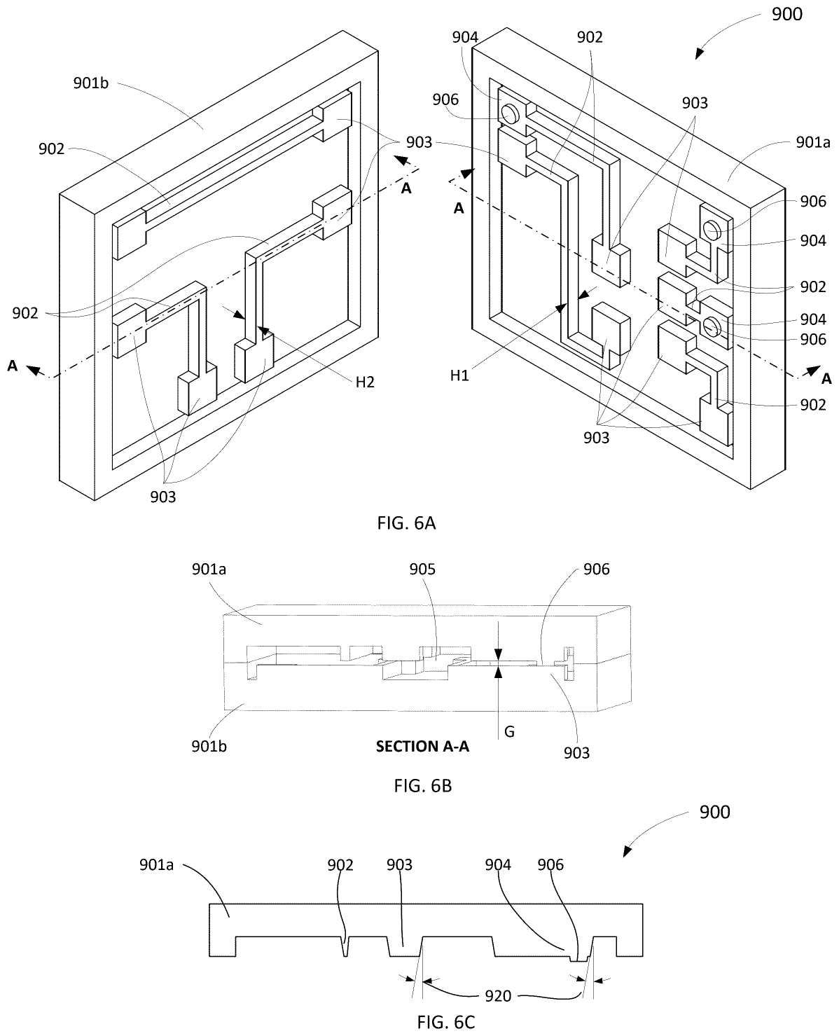

FIG. 6A shows an embodiment of a clamshell mold 900 that can be used to form the 3D dielectric substrate 800 shown in FIGS. 5A and 5B. The clamshell mold 900 can have two adjoining sections 901a and 901b made of metal such as carbon steel, stainless steel, aluminum, or titanium, for example. It can have ridges 902 that can form the channels 802, and pads 903 that can form pockets 803 in the 3D dielectric substrate 800. The height “H1” of the ridges 902 and pads 903 in section 901a is the same or substantially the same as the thickness “T1” (FIG. 7B) of the conductive traces and pads of the PCB panel 1000). The height “H2” of the ridges 902 and pads 903 in section 901b is the same or substantially the same as the thickness “T2” of the conductive traces and pads of the PCB panel 1000. In some embodiments the heights “H1” and “H2”, and corresponding thicknesses “T1” and “T2”, can be the same or within 25 μm of each other, and in others they can be different.

Although FIGS. 6A and 6B depict an embodiment of clamshell mold 900 that corresponds to a two-sided 3D dielectric substrate 800 where the layouts in each side are different, it should be understood that in some embodiments the side layouts can be identical, so the mold sections 901a and 901b would mirror each other. In other embodiments where the 3D dielectric substrate 800 has only one side, the corresponding mold 900 would have ridges and pads on only one section, while the other section can be a flat plate.

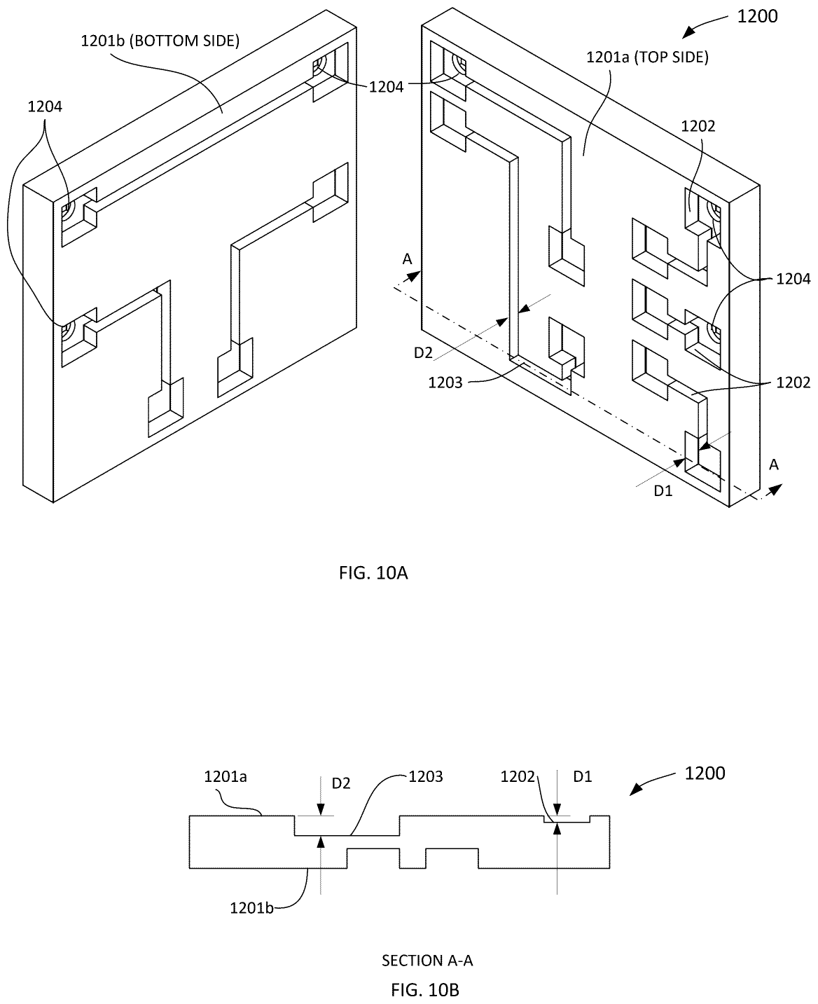

In addition, one section of the mold, section 901a for example, can have pads 904 comprising protruding bosses 906 that abut against pads 903 in the opposite section of the mold, section 901b, for example, so when the mold 900 is closed there is no gap between the boss 906 on pad 904 and the corresponding pad 903, as shown in FIG. 10B, which shows a sectional view of the closed clamshell mold 900. The boss 906 on pads 904 can form the openings 804 in the 3D dielectric substrate 800 shown in FIGS. 5A and 5B.

When the mold 900 is closed (FIG. 6B), its two sections 901a and 901b form a cavity 905 that can be filled with a fiber-reinforced polymer, such as NEMA FR-4 glass epoxy laminate, glass-reinforced polyimide laminate, or ceramic-reinforced polytetrafluorethylene resin based laminate, for example, to form the 3D dielectric substrate 800 shown in FIGS. 5A and 5B. While the mold 900 shown in FIGS. 6A and 6B has three pads 904 with protruding bosses 906, other embodiments can have a different number of pads 904 with bosses 906, or only pads 903 without bosses. As shown in FIG. 6B, the clamshell mold 900 can be built in such way that when it is closed it can have a gap between opposing ridges 902 and/or pads 903 with a width “G” that can be filled with dielectric material. The height of the bosses 906 can be the same or substantially the same as the width “G”. Since pads 904 have bosses 906, there can be no gap between portions of the opposing surfaces of the mold 900 where the pads 906 are located.

In some embodiments, the 3D dielectric substrate 800 can be formed by machining the channels 802, pads 803 and openings 804 in a dielectric plate made of a fiber-reinforced polymer, such as NEMA FR-4 glass epoxy laminate, glass-reinforced polyimide laminate, or ceramic-reinforced polytetrafluorethylene resin based laminate, for example. In those cases, the mold 900 would not be required.

FIG. 6C shows an alternate embodiment of the mold 900 where the side walls of ridges 902, pads 903 and 904 and bosses 906 can have a draft angle 920, with a range between about 0 degrees and about 5 degrees, to facilitate removing the 3D dielectric substrate 800 from mold 900 after molding step 701 (FIG. 4). The draft angle 920 also can facilitate the electrolytic metallization step 707 (FIG. 4). Some embodiments of the mold 900 can have a draft angle 920 in a range of at least about 5 degrees to at least about 15 degrees. Other examples can be about 10 degrees, in a range of 8 to 12 degrees, in a range of 5 to 20 degrees, or in a range of 5 to 30 degrees.

Once the 3D dielectric substrate 800 is formed, it can undergo an inspection step 702 (FIG. 4) followed by metallization 703, and then coated with a resist film 704 that can cover the surfaces of sides 801a and 801b (FIGS. 5A-5B) of the 3D dielectric substrate 800, except its channels 802 and pockets 803. The resist can be exposed to UV light and developed (steps 705 and 706). The 3D dielectric substrate 800 then can undergo an electrolytic metallization step 707 where the channels 802 and pads 803 and openings 804 can be completely filled with a highly conductive material 805 (FIGS. 7A-7B), such as copper or aluminum, for example. After electrolytic metallization, the resist can be stripped out from the surfaces of sides 801a and 801b in step 708, followed by a micro-etch step 709 intended to remove the metallization applied in step 703 on the surfaces of sides 801a and 801b. In some cases, the high conductive material applied in the electrolytic metallization step 707 can protrude above the surfaces of sides 801a and 801b (i.e., it can overfill them) of the 3D dielectric substrate 800, which is undesirable because it creates an uneven surface that can cause voids in subsequent lamination steps such as step 712 (FIG. 4), for example. Such voids can weaken the PCB structure and/or hinder thermal conductivity across the PCB layers. A planarization step 710 can take place to make the outer surfaces of the high conductive traces and pads deposited on the 3D substrate flush with the surfaces of sides 801a and 801b.

The resulting structure after the planarization step 710 (FIG. 4) is a two-layer PCB panel 1000 shown in FIGS. 7A and 7B, where the 3D dielectric substrate 800 has its channels 802 and pockets 803 in sides 801a and 801b (FIGS. 5A and 5B) filled with a highly conductive material 805 (FIGS. 7A and 7B) forming the conductive layers of the PCB panel 1000. The traces and pads 805 that form the conductive layers of PCB panel 1000 are flush with sides 801a and 801b (FIGS. 5A and 5B). FIG. 7B shows a sectional view where the openings 804 (FIGS. 5A and 5B) are filled with the highly conductive material 805 forming a connection 806 between the conductive layers of the PCB panel 1000.

FIG. 7C shows an alternate embodiment of the two-layer PCB panel 1000 where the 3D dielectric substrate 800 is formed in a mold 900 (FIGS. 6A-6C) where the side walls of ridges 902, pads 903 and 904 and bosses 906 have a draft angle 920 (FIG. 6C) between about 0 degrees and about 5 degrees. In these embodiments, the channels 802, pockets 803 and openings 804 of the 3D dielectric substrate 800 can have corresponding draft angles 820, and those channels 802, pockets 803 and openings 804 can be completely filled with the highly conductive material 805 during the electrolytic metallization step 707 (FIG. 4). Some embodiments of the mold 900 that have a draft angle 920 in a range of at least about 5 degrees to at least about 15 degrees can produce substrates 800 with draft angles 820 within the same range, or any of the other values or ranges described herein.

Some embodiments of the 3D dielectric substrate 800 that are formed by machining can also have channels 802 and pads 803 with draft angles 820 in a range of at least about 0 degrees and at least about 5 degrees, or at least about 5 degrees and at least about 15 degrees, or any of the other values or ranges described herein, depending on the PCB design requirements. The desired draft angle can be achieved by utilizing tapered cutting tools to machine the 3D dielectric substrate 800, for example.

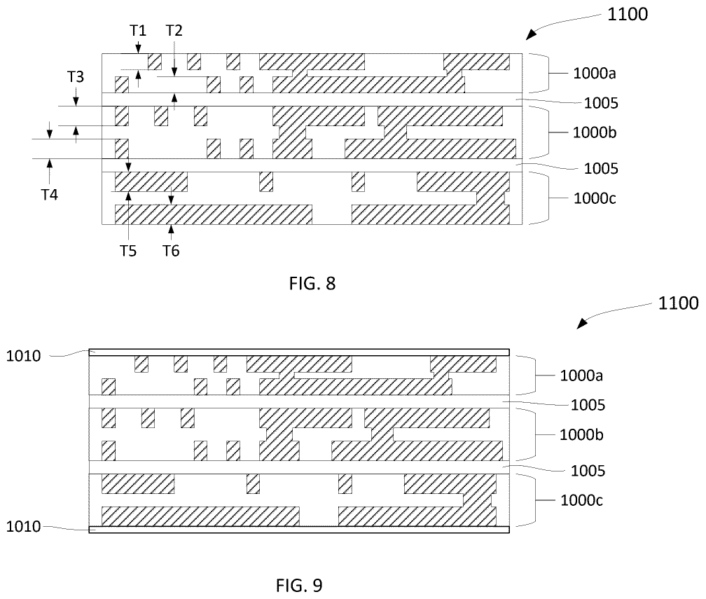

In some embodiments where the final PCB can have more than two conductive layers, a plurality of PCB panels can be inspected (step 711 in FIG. 4), stacked and laminated together in step 712. FIG. 8 shows an example of a PCB 1100 comprising six conductive layers built with three PCB panels 1000a, 1000b and 1000c interleaved with dielectric layers 1005. The dielectric layers 1005 can be made of a fiber-reinforced polymer, as described herein. The PCB panels 1000a, 1000b and 1000c can have the same or different layouts. For example, the PCB panel 1000a can have two layers with thicknesses “T1” and “T2” respectively, PCB panel 1000b can have two layers with thicknesses “T3” and “T4” respectively, and PCB panel 1000c can have two layers with thicknesses “T5” and “T6”.

Embodiments of the PCB 1100 can be built with a combination of two and one-layer PCB panels. Other embodiments can have panels comprising conductive layers having the same thickness. Other embodiments yet can have some or all conductive layers having the same layout. Some embodiments of the PCB 1100 can have a combination of multiple panels with one or two conductive layers, some of the conductive layers can have the same thickness, and/or some of the conductive layers can have the same layout.

After the lamination process 712 (FIG. 4), the PCB structure can undergo via drilling, metallization and plating as per steps 713 through 722. Some embodiments of the PCB 1100 where lamination and via drilling is not required, the PCB 1100 can go from panel inspection (step 711 in FIG. 4) straight to solder mask application, step 723 through 726, and proceed through finishing steps 727 through 732 (FIG. 4). In other embodiments, like the one shown in FIG. 9, the lamination step 712 of the PCB 1100 can include external dielectric layers 1010. In this case, the PCB 1100 would not need application of solder mask, thus undergoing the via drilling, metallization, and plating steps 713 through 722, then going straight to the finishing steps 727 through 732 (FIG. 4).

Some embodiments of the PCB structure can have traces and pads with different thicknesses in the same conductive layer. FIGS. 10A and 10B show an embodiment of a 3D dielectric substrate 1200 with a first side 1201a, also referred to as “top side,” can have at least one channel and/or pocket 1203 with a depth “D2” different from the depth “D1” of the other channels and/or pockets 1202 in the side 1201a. The 3D dielectric structure 1200 can have a second side 1201b (also referred to as “bottom side”) opposite to the side 1201a with its respective channels and pockets, similar to the embodiment depicted in FIGS. 5A and 5B. In that case, the 3D dielectric substrate 1200 can have openings 1204 to connect the two sides of the 3D dielectric substrate 1200. In some embodiments, the 3D dielectric substrate 1200 can have channels and/or pockets 1202, 1203 in only one side, in which case the other side can be flat. Although, the embodiment depicted in FIGS. 10A and 10B has channels and/or pockets 1202, 1203 with different depths on one side, it should be understood that other embodiments can have traces and/or pockets with different depths on both sides. Furthermore, some embodiments can have channels and/or pockets with many different depths. The 3D dielectric substrate 1200 can be formed from a fiber-reinforced polymer, as described herein.

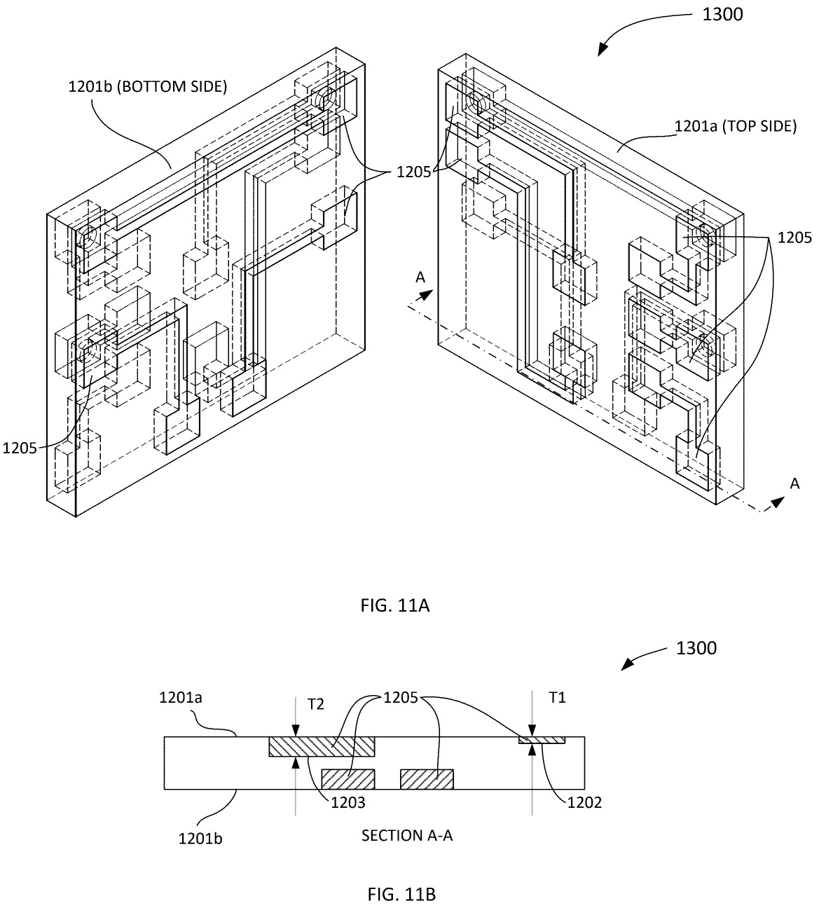

In the electrolytic metallization step 707 (FIG. 4) the channels and pockets of the 3D dielectric substrate 1200 can be completely filled with highly conductive material 1205, such as copper or aluminum, for example, forming conductive layers in a PCB structure 1300. FIGS. 11A and 11B depict a PCB structure 1300 after the planarization step 710 (FIG. 4) where the channels and/or pockets 1202 (FIG. 10A) are filled with the highly conductive material 1205 forming traces and/or pads with thickness “T1” and the channels and/or pockets 1203 are filled with the highly conductive material 1205 forming traces and/or pads with thickness “T2”. The thicknesses “T1” and “T2” (FIG. 11B) correspond to the depths “D1” and “D2” (FIG. 10B), respectively, of the 3D dielectric substrate 1200. As depicted in FIGS. 11A and 11B, some embodiments of the PCB structure 1300 can have a highly conductive material 1205 deposited on both sides 1201a and 1201b of the structure. Other versions can have the conductive material deposited on only one side. In all embodiments, the outer surfaces of traces and pads of highly conductive material can be flush with the top (1201a) and/or bottom (1201b) sides of the PCB structure 1300.

FIG. 12 shows a partial view of a PCB stator 2000 employed in an axial field rotary energy device similar to the one described in U.S. Pat. No. 10,141,803, 10, 135,310, 10,340,760, 10,141,804, 10,186,922, and 11,502.583, for example. The PCB stator 2000 can have a plurality of conductive layers and each conductive layer can have a plurality of coils 2001.

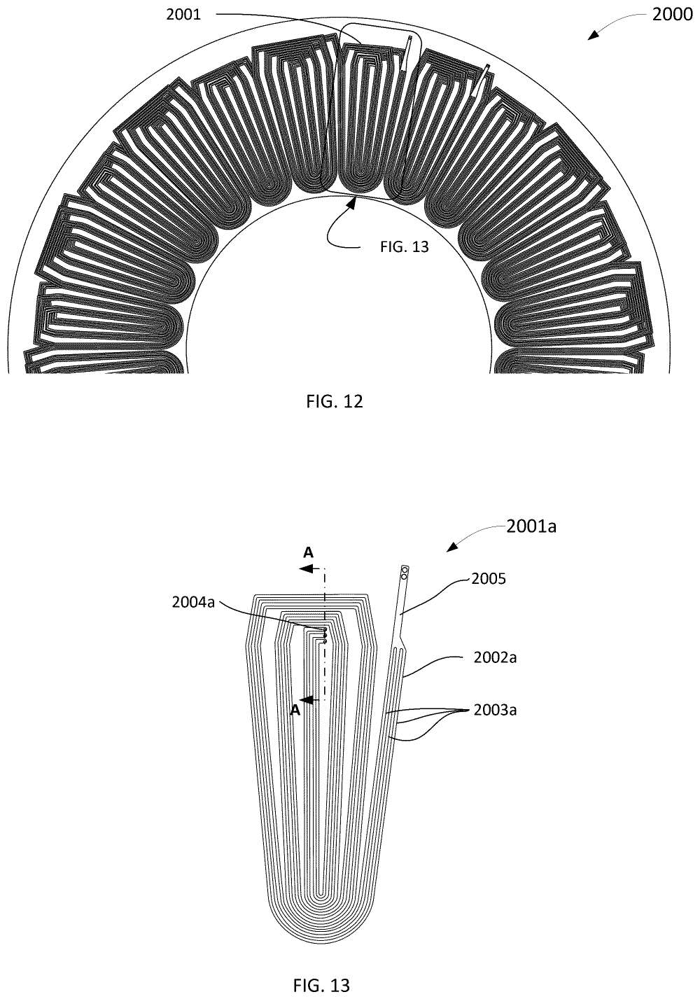

FIG. 13 shows an isolated coil 2001 of PCB stator 2000. Hereinafter, coil 2001 can be referred to as coil 2001a. Although coil 2001a shown in FIG. 13 has three turns 2002a and each turn 2002a has three traces 2003a in parallel, other embodiments of the PCB stator 2000 can have coils 2001a with 1, 2, 4 or more turns, and each turn in those embodiments can have 1, 2, 4 or more traces in parallel. Each of the traces 2003a in coil 2001a can be terminated in a pad 2004a, or can merge with other traces to form a terminal 2005 that can be connected to another PCB stator or to a power supply. Although FIG. 13 shows a coil 2001a with a terminal 2005, other embodiments of coil 2001a can have traces 2003a terminated in pads 2004a at both ends of each trace 2003a. Pad 2004a can be connected to another pad in another coil located in another layer of the PCB stator 2000, in some examples.

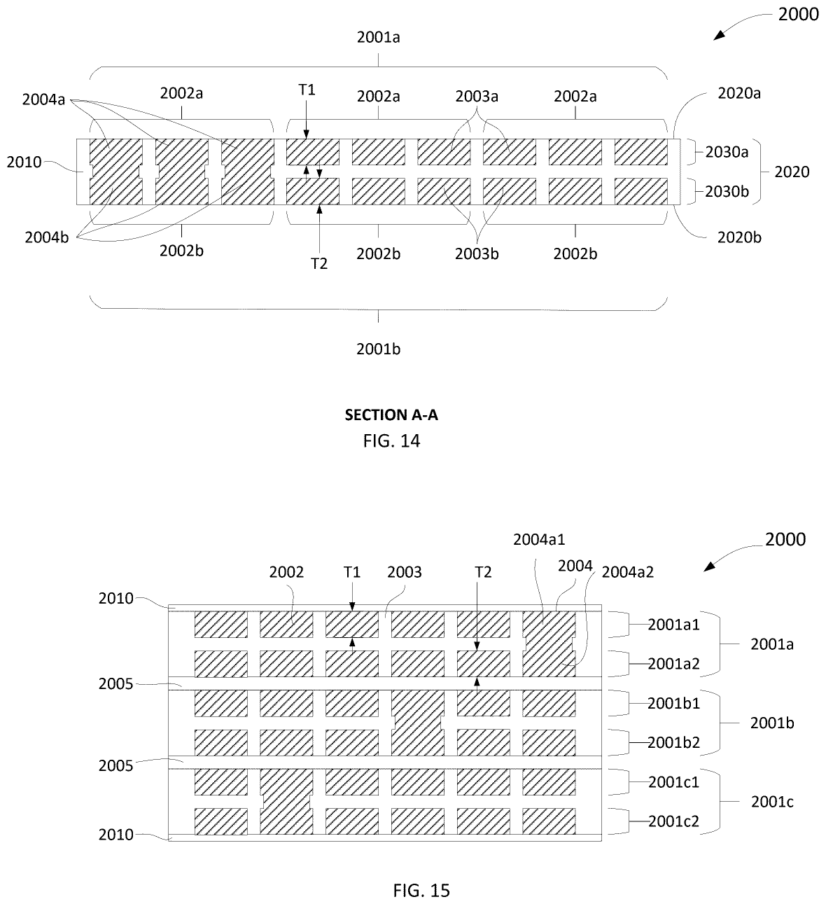

FIG. 14 depicts a sectional side view A-A of PCB stator 2000 showing coil 2001a with its turns 2002a, traces 2003a, and pads 2004a located in a layer 2030a and an adjacent coil 2001b located in a different layer 2030b of the PCB stator 2000. Coil 2001b can have turns 2002b and pads 2004b. Each turn of coil 2001b can have traces 2003b. The pads 2004a and 2004b of coils 2001a and 2001b, respectively, can be interconnected. Although FIG. 14 shows a coil 2001b substantially similar to coil 2001a having three turns 2002b and each turn having three traces 2003b in parallel, other embodiments of the PCB stator 2000 can have coils 2001b with any number of turns and any number of traces in parallel. Moreover, some embodiments of the PCB stator 2000 can have coils 2001a and 2002b with different numbers of turns, respectively. In the embodiment shown in FIG. 14, layers 2030a, b can be formed in the same 3D dielectric substrate 2010, which together with the conductive traces 2003a and 2003b form a PCB panel 2020. The PCB panel 2020 can be formed by completely filling the channels and pockets of the 3D dielectric substrate 2010 with a highly conductive material in a electrolytic metallization step 707, as described in the process 700 shown in FIG. 4. The PCB panel 2020 can undergo a planarization step 710 to make the outer surfaces of the highly conductive traces 2003a and 2003b and pads 2004a and 2004b flush with the surfaces 2020a and 2020b of the PCB panel 2020.

In the PCB stator 2000 embodiment shown in FIG. 14, the thickness “T1” of layer 2030a and thickness “T2” of layer 2030b are the same or substantially the same. In other embodiments, however, the thicknesses “T1” and “T2” can be different.

Embodiments of the PCB stator 2000 can have a plurality of PCB panels 2020 connected in parallel and/or assigned to different electrical phases. The example of a PCB stator 2000 shown in FIG. 15 depicts a sectional side view of a 3-phase PCB stator with three panels, where each panel 2001a, 2001b, and 2001c can be assigned to a respective electrical phase. The PCB stator 2000 shown in FIG. 15 can be used in an axial field rotary energy device. The PCB stator 2000 can have three, two-layer panels 2001a, 2001b and 2001c laminated together with interleaved layers of a dielectric material 2005 and with external dielectric layers 2010. As an example, panel 2001a has layers 2001a1 and 2001a2. Each panel 2001a-2001c can be formed by depositing an electrically conductive material 2002 (e.g., step 707 in process 700 shown in FIG. 4), such as copper, for example, into the channels and pockets formed in a 3D dielectric substrate 2003. Some pockets 2004 can be interconnected to a corresponding pocket in the other layer of the PCB panel 2020. As an example, pocket 2004a1 in layer 2001a1 of panel 2001a is connected to pocket 2004a2 of layer 2001a2 of the same panel 2001a. In the embodiment depicted in FIG. 15, the thickness of the two layers in each panel can be the same. As an example, the thickness “T1” of layer 2001a1 of panel 2001a is the same or substantially the same as thickness “T2” of layer 2001a2 of the same panel 2001a, and the thicknesses of the layers 2001b1, 2001b2, 2001c1 and 2001c2 of the panels 2001b and 2001c, respectively, can be the same or substantially the same as “T1” or “T2”. However, other embodiments may have different thicknesses “T1” and “T2” or can have different thicknesses in each one of the layers of each panel. Some embodiments of PCB stator 2000 can have more than one PCB panel (e.g., 2001a, 2001b and 2001c) assigned to each corresponding phase, and other embodiments of PCB stator 2000 can have 1, 2 or more than 3 phases with a plurality of PCB panels assigned to each phase.

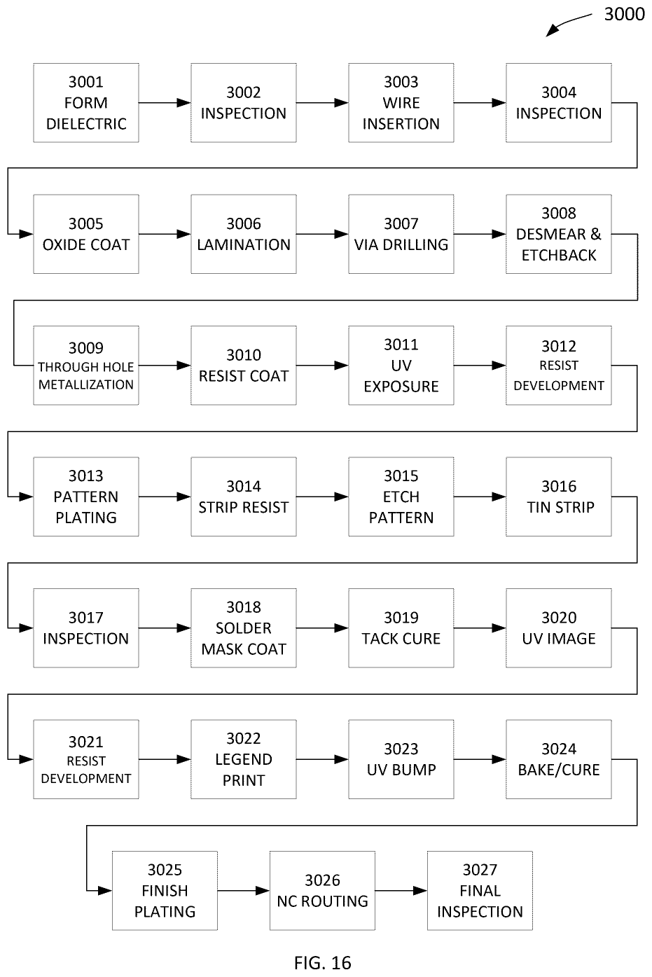

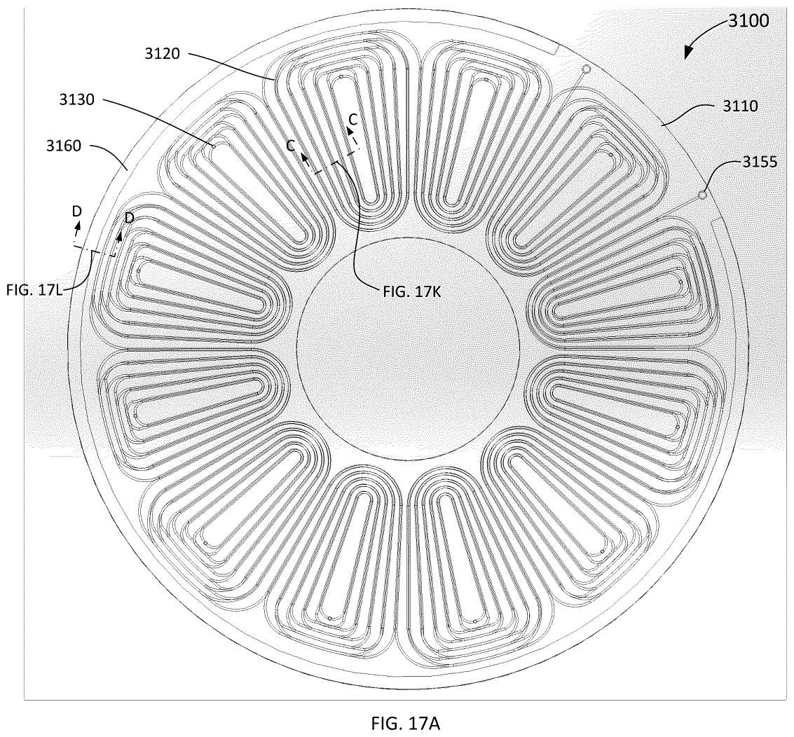

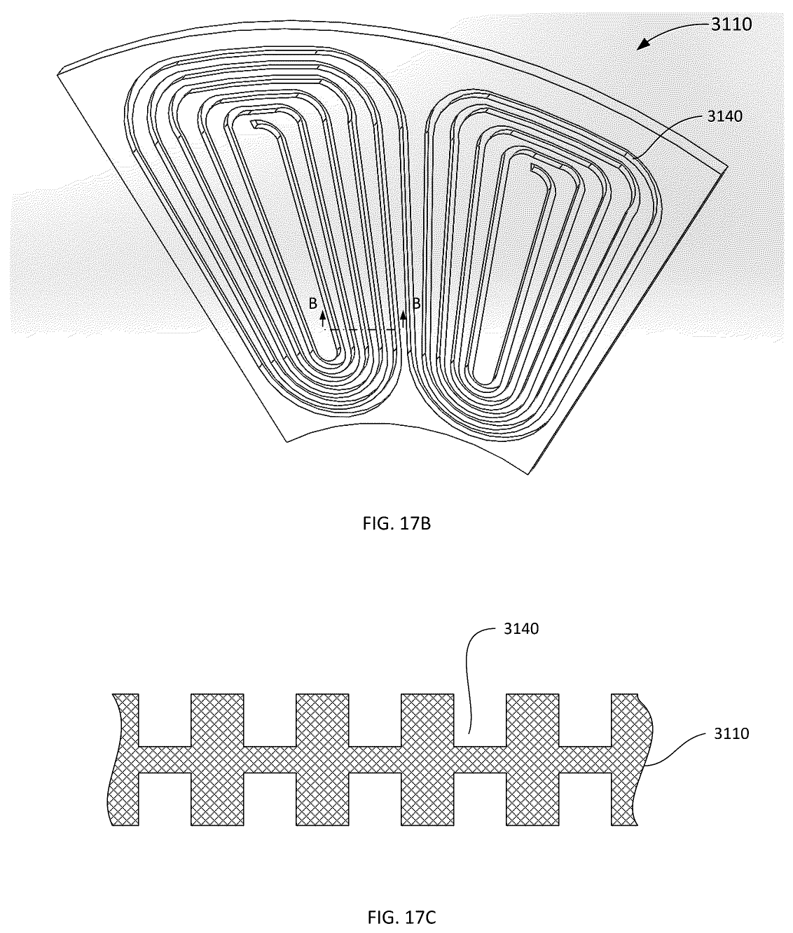

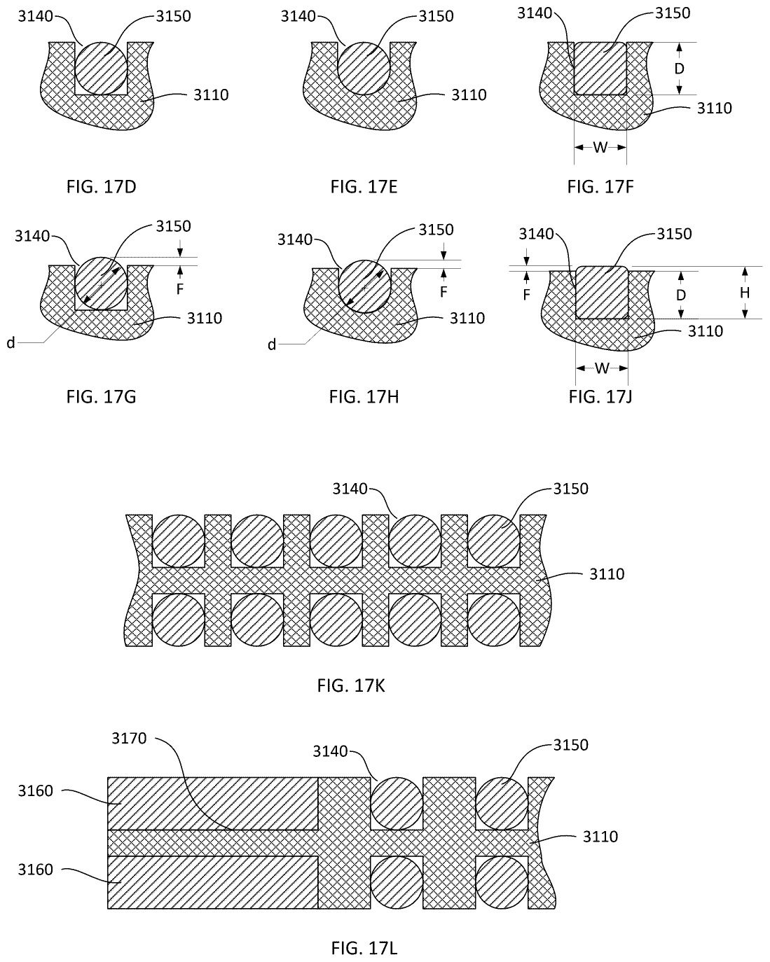

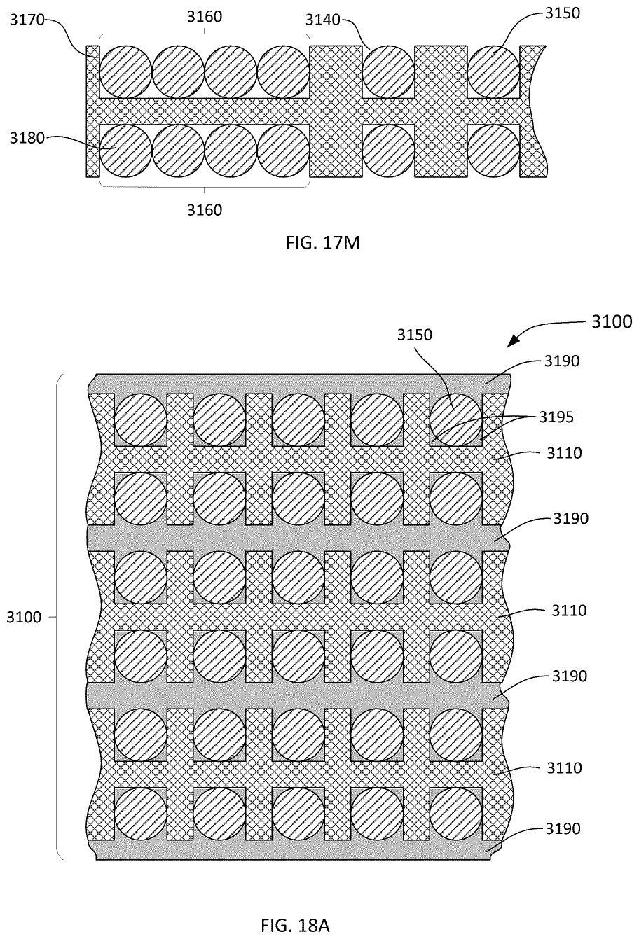

FIG. 16 shows an alternate manufacturing process 3000 to build a PCB, such as a PCB stator 3100 (FIG. 17A), that can be used in an axial field rotary energy device. This alternate process utilizes wire insertion (step 3003, FIG. 16) instead of plating as previously taught in process 700 (FIG. 4). The first step 3001 in process 3000 includes forming a 3D dielectric substrate, such as by molding a B-stage dielectric material made of a fiber-reinforced polymer, or by machining a fiber-reinforced laminate such as NEMA FR-4 glass epoxy laminate, for example. The PCB stator 3100 (FIG. 17A) can have at least one 3D dielectric substrate 3110 configured to carry coils 3120 on both sides thereof. Similar to process 700, process 3000 is intended to produce a conductive structure in the 3D dielectric substrate 3110 with, for example, a conductive structure thickness of 140 μm or more.

FIG. 17B shows a partial view of a 3D dielectric substrate 3110 showing the channels 3140 formed therein. FIG. 17C shows a sectional view of the 3D dielectric substrate 3110, taken along the lines B-B of FIG. 17B, having channels 3140 on both sides. In some embodiments, there can be channels on only one side of the 3D dielectric substrate 3110. The shape of the channels 3140 can be configured to receive different types of conductive wires that can form coils 3120 (FIG. 17A), as discussed below.

Continuing with process 3000, (FIG. 16) the 3D dielectric substrate 3110 can undergo a visual inspection, step 3002, before wire insertion, step 3003, which includes pushing a conductive wire into the channels 3140 (FIG. 17B) of the 3D substrate 3110 by any suitable mean, such as with a robotic dispensing machine, for example. As shown in FIGS. 17D-17E, the conductive wire 3150 can be round and be inserted in a channel 3140 (FIG. 17D) that is substantially rectangular or square. In some embodiments, the channel 3140 can have a round bottom (FIG. 17E) that is complementary in shape to the conductive wire 3150 (FIG. 17E) that is round. In other embodiments, the channel 3140 can have a rectangular shape (FIGS. 17D and 17F). In the embodiment of FIG. 17F, the channel 3140 has a width W and depth D that match the width and height, respectively, of a conductive wire 3150 that is rectangular. In some examples, the width W and depth D can be equal, and the conductive wire 3150 can be square. While FIGS. 17D to 17F shows embodiments where the top side of the conductive wire 3150 is flush or substantially flush with the outer surface of the 3D substrate 3110, other embodiments can have the depth of the channel 3140 up to 50% less than the diameter d of the conductive wire 3150 that is round, as shown in FIGS. 17G and 17H. The conductive wire 3150 can protrude a distance F above the outer surface of the 3D dielectric substrate 3110. In other embodiments, where the conductive wire 3150 is rectangular, the depth D of the channel 3140 can be up to 50% less than the height H of the conductive wire 3150. In those cases, the conductive wire 3150 can protrude a distance F above the surface of the 3D dielectric substrate 3110.

The conductive wire 3150 can be made of copper or aluminum, for example. In some embodiments the conductive wire can be solid and in others can comprise a plurality of strands, such as a cable. In some embodiments, the conductive wire 3150 can have an insulating coat, in which cases it is called a “magnet wire”. The conductive wire 3150 can a have a diameter equivalent to 20 AWG or 22 AWG, in some examples.

At the end of step 3003 (FIG. 16) in process 3000, the 3D dielectric substrate 3110 (FIG. 17K) can have conductive wires 3150 inserted into its channels 3140 to form coils 3120 (FIG. 17A) in the PCB stator 3100. FIG. 17K is a sectional view of FIG. 17A, taken along the line C-C. Some embodiments of the PCB stator 3100 can have a ground pad 3160 (FIGS. 17A and 17L) comprising a strip of conductive material such as copper or aluminum, for example, inserted in a channel 3170 in the 3D dielectric substrate 3110 that is configured to receive the ground pad 3160. FIG. 17L is a sectional view of FIG. 17A, taken along the line D-D. The ground pad 3160 can have the same thickness as the conductive wires 3150, for example. Other embodiments of the PCB stator 3100 can have the ground pad 3160 built by inserting a plurality of conductive wires 3180 (FIG. 17M) in a channel 3170 on one or both sides of the substrate. The conductive wires 3180 can be inserted into channel 3170 using the same process used to insert conductive wires 3150 in the channels 3140 for the other embodiments. The conductive wires 3180 can be made of the same material as conductive wires 3150 (copper or aluminum, for example). Conductive wires 3180 can have the same dimensions and shape as conductive wires 3150. However, in some embodiments conductive wires 3180 can have a different shape and/or dimensions than conductive wires 3150.

Continuing with process 3000 (FIG. 16), the 3D dielectric substrate 3110, now with coils 3120 formed by conductive wires 3150 and, in some cases, having ground pads 3160, can undergo an inspection step 3004. That can be followed by an oxide coat step 3005 intended to promote better adhesion between the conductive wires 3150 and a B-stage dielectric material made of fiber-reinforced polymer applied in the lamination step 3006. In some embodiments of process 3000, the oxide coat step 3005 can be skipped.

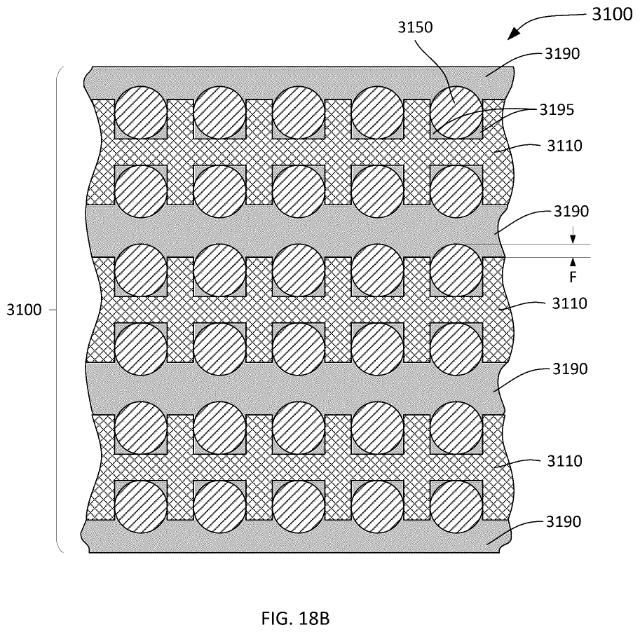

In the lamination step 3006, one or more 3D dielectric substrates 3110 with respective coils 3120 and ground pads 3160 (optional) can be stacked together and interleaved with B-stage sheets of fiber reinforced polymer 3190 (FIGS. 18A and 18B) to form the PCB stator 3100 with multiple layers. The lamination step 3006 can include pressing and heating the stack of 3D dielectric substrates 3110 and B-stage sheets of fiber-reinforced polymer 3190 so the resin in the B-stage sheets can flow around the conductive wires 3150 to fill all gaps 3195 (FIGS. 18A and 18B) between the conductive wires 3150 and respective 3D dielectric substrates 3110. This can anchor the conductive wires 3150 to the 3D dielectric substrates 3110 and prevent them from moving during the operation of the PCB stator 3100 when mounted in an axial field rotary energy device. In the embodiment shown in FIG. 18A, the conductive wires 3150 are flush with the outer surface of the 3D dielectric substrate 3110, while in the embodiment shown in FIG. 18B, the conductive wires 3150 protrude a distance F above the surface of the dielectric substrate 3110. In each example, the conductor wires in the PCB stator are surrounded, completely surrounded or encapsulated by the resin that anchors them to the dielectric substrate. The conductor wires are not overwrapped or taped to the PCB stator.

The PCB stator 3100 shown in FIGS. 17A, 18A and 18B can be a 3-phase stator (e.g., two layers per phase) for an axial field energy device. Although FIGS. 18A and 18B show a schematic sectional view of the PCB stator 3100 with three 3D dielectric substrates 3110 forming a six-layer structure, it should be understood that other embodiments of the PCB stator 3100 can have a different number of layers. For example, an embodiment of the PCB stator 3100 can have three phases with six 3D dielectric substrates 3110 forming a 12-layer structure with four layers assigned to each one of the three phases of the PCB stator 3100.

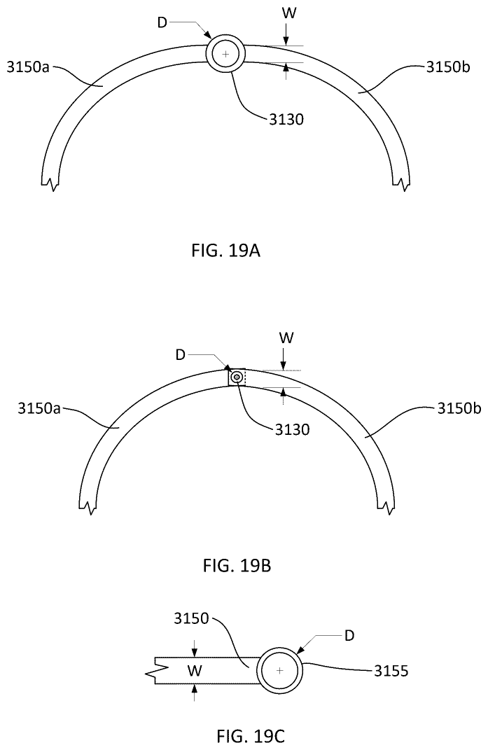

Continuing with process 3000, step 3007 can include drilling via holes in the 3D substrate in preparation for the pattern plating step 3013, to form vias that interconnect the conductive wires in the PCB stator. The via hole drilling is followed by a desmear step 3008, which includes removing the resin smear residues on the hole walls due to the drilling operation, followed by a metallization step 3009 of the drilled holes. The metallization step 3009 can be accomplished through electroless metal deposition or graphite deposition, for example. The following steps-resist coat (3010), UV exposure (3011) and resist development (3012)—are intended to protect areas in the PCB stator that do not need to be plated during the pattern plating step 3013. The pattern plating step 3013 electrolytically deposits a conductive material (e.g., copper or aluminum) in the drilled holes to form plated vias 3130 (FIGS. 17A, 19A and 19B) that connect conductive wires 3150a and 3150b that are located in different layers of the PCB stator. In the embodiment shown in FIG. 19A, the diameter D of the plated via 3130 can be larger than the width W of the conductive wires 3150a and 3150b. In the embodiment shown in FIG. 19B, the diameter D of the plated via 3130 can be smaller than the width W of the conductive wires 3150a and 3150b, such that the plated via 3155 is completely circumscribed by the conductive wires 3150a and 3150b. The pattern plating step 3013 (FIG. 16) also can form the terminals 3155 (FIGS. 17A and 19C) of the PCB stator. As shown in FIG. 19C the conductive wire 3150 can be terminated in a plated via 3155 that can have a diameter D larger than the wire width W. In some embodiments, the via hole drilling step 3007 can be formed in the ground pads 3160 as well. After pattern plating step 3013, the ground pads 3160 can be interconnected with vias.

Continuing on with process 3000 in FIG. 16, the steps following pattern plating step 3013 are typical PCB manufacturing operations: strip resist 3014, etch pattern 3015, tin strip 3016, and inspection 3017. Some embodiments of the PCB stator can have a solder mask coat, in which case they can undergo steps 3018 through 3024 (solder mask coat, tack cure, UV image, resist development, legend print, UV bump and bake/cure). In other embodiments of the PCB stator, a solder mask coat is not required so the process moves from inspection step 3017 directly to finish plating step 3025, which can include plating exposed metal areas of the PCB stator with a corrosion resistant conductive metal, such as ENIG (electroless nickel immersion gold), for example. In these embodiments, the legend print step 3022 and UV bump step 3023 can occur before or after finish plating step 3025. After finish plating step 3025, the PCB stator undergoes NC routing 3026 and final inspection 3027.

Other embodiments can include one or more of the following items.

1. A printed circuit board (PCB), comprising:
a tridimensional (3D) dielectric substrate having opposite sides and made of fiber-reinforced polymer;
each side comprises channels and pockets formed by molding a dielectric laminate, and the channels and pockets define a layout for conductive traces and pads of the PCB;
the channels and pockets in a same side of the 3D dielectric substrate have a uniform depth;
side walls of the channels and pockets have a draft angle in a range of greater than 0 degrees to about 5 degrees;
the conductive traces and pads are formed into the channels and pockets by electrolytic metallization; and
the outer surface of conductive traces and pads are flush with the sides of the 3D dielectric substrate.

2. The PCB wherein the channels and pockets of a first side of the sides of the 3D dielectric substrate have a first depth, the channels and pockets of a second side of the sides of the 3D dielectric substrate have a second depth.

3. The PCB wherein the first and second depths are the same or within 25 μm of each other.

4. The PCB wherein the sides have a same layout.

5. The PCB wherein each side has a different layout.

6. The PCB wherein the first depth differs from the second depth.

7. The PCB wherein the sides have a same layout.

8. The PCB wherein each side has a different layout.

9. The PCB further comprising a plurality of 3D dielectric substrates, wherein each side of the 3D dielectric substrates has a different layout.

10. The PCB wherein the channels and pockets in each side have a different depth from those in another side.

11. The PCB wherein the uniform depth of the channels and pockets is equal to or greater than 140 μm.

12. A printed circuit board (PCB), comprising:
a tridimensional (3D) fiber-reinforced polymer dielectric substrate having opposite sides;
each side comprises channels and pockets formed by molding a dielectric laminate, and the channels and pockets define a layout for conductive traces and pads of the PCB;
the channels and pockets in a same side of the 3D dielectric substrate have non-uniform depths;
side walls of the channels and pockets have a draft angle in a range of greater than 0 degrees to about 5 degrees;
the conductive traces and pads are formed into the channels and pockets by electrolytic metallization; and
the outer surface of conductive traces and pads are flush with the sides of the 3D dielectric substrate.

13. A printed circuit board (PCB) stator for an axial field rotary energy device, the PCB stator comprising:
PCB panels, each comprising a tridimensional (3D) dielectric substrate with opposite sides and made of fiber-reinforced polymer;
each side comprises channels and pockets comprising molded dielectric laminate, the channels and pockets in each side have a uniform depth, and the channels and pockets comprise a layout of conductive traces and pads that are plated therein and the outer surface of those conductive traces and pads are flush with the sides of the 3D dielectric substrate; and
side walls of the channels and pockets have a draft angle in a range of greater than 0 degrees to about 5 degrees.

14. The PCB stator wherein the channels and pockets of a first side of the sides of the PCB panels have a first depth, the channels and pockets of a second side of the sides of the PCB panels have a second depth.

15. The PCB stator wherein the first and second depths are the same or within 25 μm of each other.

16. The PCB stator wherein the sides of each PCB panel have a same layout.

17. The PCB stator wherein the sides of each PCB panel have a different layout.

18. The PCB stator wherein the first depth differs from the second depth.

19. The PCB stator wherein the sides of each PCB panel have a same layout.

20. The PCB stator wherein the sides of each PCB panel have a different layout.

21. The PCB stator wherein the uniform depth of the channels and pockets is equal to or greater than 140 μm.

22. A method of manufacturing a printed circuit board (PCB), the method comprising:
forming a tridimensional (3D) dielectric substrate on a fiber-reinforced polymer with opposite sides;
forming each side with channels and pockets by molding dielectric laminate, and the channels and pockets define a layout for conductive traces and pads of the PCB;
forming the channels and pockets in a same side of the 3D dielectric substrate at a uniform depth;
forming side walls of the channels and pockets of the 3D dielectric substrate with a draft angle in a range of greater than 0 degrees to about 5 degrees;
depositing by electrolytic metallization the conductive traces and pads into the channels and pockets of the 3D dielectric substrate; and
the outer surface of those conductive traces and pads are flush with the sides of the 3D dielectric substrate.

23. The method wherein the channels and pockets of a first side of the sides comprise a first depth, and the channels and pockets of a second side of the sides comprise a second depth.

24. The method wherein the first and second depths are the same or within 25 μm of each other.

25. The method wherein the sides of the 3D dielectric substrate are formed with a same layout.

26. The method wherein each side of the 3D dielectric substrate is formed with a different layout.

27. The method wherein the first depth differs from the second depth.

28. The method wherein the sides of the 3D dielectric substrate are formed with a same layout.

29. The method wherein each side of the 3D dielectric substrate is formed with a different layout.

30 A method of manufacturing a printed circuit board (PCB), the method comprising:
forming a tridimensional (3D) fiber-reinforced polymer dielectric substrate with opposite sides;
forming each side with channels and pockets by molding dielectric laminate, and the channels and pockets define a layout for conductive traces and pads of the PCB;
forming the channels and pockets in a same side of the 3D dielectric substrate with non-uniform depths;
forming side walls of the channels and pockets of the 3D dielectric substrate with a draft angle in a range of greater than 0 degrees to about 5 degrees; and
depositing by electrolytic metallization the conductive traces and pads into the channels and pockets of the 3D dielectric substrate; and
the outer surface of those conductive traces and pads are flush with the sides of the 3D dielectric substrate.

31. A method of manufacturing a printed circuit board (PCB) stator for an axial field rotary energy device, the method comprising:
forming a PCB panel as a tridimensional (3D) fiber-reinforced polymer dielectric substrate with opposite sides;
each side comprises channels and pockets formed by molding dielectric laminate, and the channels and pockets define a layout for conductive traces and pads of the PCB stator;
the channels and pockets in a same side of the 3D dielectric substrate have a uniform depth;
side walls of the channels and pockets of the 3D dielectric substrate have a draft angle in a range of greater than 0 degrees to about 5 degrees; and
depositing by electrolytic metallization and forming the conductive traces and pads into the channels and pockets of the 3D dielectric substrate; and
the outer surface of those conductive traces and pads are flush with the sides of the 3D dielectric substrate.

32. The method wherein the channels and pockets of a first side of the sides of the 3D dielectric substrate are formed at a first depth, and the channels and pockets of a second side of the sides of the 3D dielectric substrate are formed at a second depth.

33. The method wherein the first and second depths are the same or within 25 μm of each other.

34. The method wherein the first depth differs from the second depth.

35. The method wherein the channels and pockets are formed with the uniform depth equal to or greater than 140 μm.

Still other embodiments can include one or more of the following items.

1. A printed circuit board (PCB) stator for an axial field rotary energy device, the PCB stator comprising:
PCB panels, each comprising a dielectric substrate of fiber-reinforced polymer with opposite sides;
channels molded or machined in each side of each PCB panel; and
conductive wires inserted into the channels, respectively, to form conductive traces, outer surfaces of the conductive traces are substantially flush with outer surfaces of the dielectric substrate, and the conductive traces are surrounded by a resin and anchored to the dielectric substrate.

2. The PCB stator wherein the channels in each side of each PCB panel have a uniform depth.

3. The PCB stator wherein the uniform depth of the channels is equal to or greater than 140 μm.

4. The PCB stator wherein the conductive wires are round in sectional shape.

5. The PCB stator wherein the conductive wires are rectangular in sectional shape.

6. The PCB stator wherein the conductive wires are solid and are not stranded.

7. The PCB stator wherein the channels have a shape that is complementary to a shape of the conductive wires.

8. The PCB stator wherein each PCB panel further comprises a ground pad.

9. The PCB stator wherein each ground pad comprises a strip of conductive material.

10. The PCB stator wherein at least some of the ground pads each comprise a plurality of conductive wires.

11. The PCB stator wherein each ground pad comprises a thickness equal to or greater than 140 μm.

12. The PCB stator wherein the conductor wires are not overwrapped or taped to the PCB stator.

13. A printed circuit board (PCB) stator for an axial field rotary energy device, the PCB stator comprising:
PCB panels, each comprising a dielectric substrate of fiber-reinforced polymer with opposite sides;
channels molded or machined in each side of each PCB panel; and
the channels comprise conductive traces that are formed by inserting conductive wires in the channels, outer surfaces of the conductive wires protrude above an outer surface of the dielectric substrate, and the conductive wires are surrounded by a resin and anchored to the dielectric substrate.

14. The PCB stator wherein the channels in each side have a uniform depth.

15. The PCB stator wherein the uniform depth of the channels is equal to or greater than 140 μm.

16. The PCB stator wherein the conductive wires are round in sectional shape.

17. The PCB stator wherein the conductive wires are rectangular in sectional shape.

18. The PCB stator wherein the conductive wires are solid and are not stranded.

19. The PCB stator wherein the channels have a shape that is complementary to a shape of the conductive wires.

20. The PCB stator wherein each PCB panel further comprises a ground pad.

21. The PCB stator wherein each ground pad comprises a strip of conductive material.

22. The PCB stator wherein each ground pad comprises a plurality of conductive wires.

23. The PCB stator wherein each ground pad comprises a thickness equal to or greater than 140 μm.

24. A method of making a printed circuit board (PCB) stator, the method comprising:
providing PCB panels comprising a dielectric substrate of fiber-reinforced polymer with opposite sides;
molding or machining channels in each side of each PCB panel;
inserting conductive wires in the channels in each side of each PCB panel to form conductive traces;
making outer surfaces of the conductive traces substantially flush with an outer surface of the dielectric substrate; and then
surrounding the conductive traces with a resin to anchor the conductive traces to the dielectric substrate.

25. The method wherein the molding or machining step comprises forming the channels at a uniform depth.

26. The method wherein the molding or machining step comprises forming the channels at a uniform depth equal to or greater than 140 μm.

27. The method wherein the conductive wires are round in sectional shape.

28 The method wherein the conductive wires are rectangular in sectional shape.

29. The method wherein the conductive wires are solid and are not stranded.

30. The method wherein the molding or machining step comprises forming the channels in a shape that is complementary to a shape of the conductive wires.

31. The method further comprising providing each PCB panel with a ground pad.

32. The method further comprising providing each PCB panel with a ground pad comprising a strip of conductive material.

33. The method further comprising providing each PCB panel with a ground pad comprising a plurality of conductive wires.

34. The method further comprising providing each PCB panel with a ground pad comprising a thickness equal to or greater than 140 μm.

35. A method of making a printed circuit board (PCB) stator, the method comprising:
providing PCB panels comprising a dielectric substrate of fiber-reinforced polymer with opposite sides;
molding or machining channels in each side of each PCB panel;
inserting conductive wires in the channels in each side of each PCB panel to form conductive traces;
making outer surfaces of the conductive traces protrude above an outer surface of the dielectric substrate; and then
surrounding the conductive traces with a resin to anchor the conductive traces to the dielectric substrate.

36. The method wherein the molding or machining step comprises forming the channels at a uniform depth.

37 The method wherein the conductive wires are round in sectional shape.

38. The method wherein the conductive wires are rectangular in sectional shape.

39. The method wherein the conductive wires are solid and are not stranded.

40. The method wherein the molding or machining step comprises forming the channels in a shape that is complementary to a shape of the conductive wires.

41. The method further comprising providing each PCB panel with a ground pad.

42. The method further comprising providing each PCB panel with a ground pad comprising a strip of conductive material.

43. The method further comprising providing each PCB panel with a ground pad comprising a plurality of conductive wires.

44. The method further comprising providing each PCB panel with a ground pad comprising a thickness equal to or greater than 140 μm.

The terminology used herein describes only particular example embodiments and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” “top”, “bottom,” and the like, may be used herein for ease of description to describe one element's or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated degrees or at other orientations) and the spatially relative descriptions used herein interpreted accordingly.

This written description uses examples to disclose the embodiments, including the best mode, and also to enable those of ordinary skill in the art to make and use the invention. The patentable scope is defined by the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

It can be advantageous to set forth definitions of certain words and phrases used throughout this patent document. The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, can mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items can be used, and only one item in the list can be needed. For example, “at least one of: A, B, and C” includes any of the following combinations: A, B, C, A and B, A and C, B and C, and A and B and C.

Moreover, various functions described herein can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), solid state drive (SSD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Also, the use of “a” or “an” is employed to describe elements and components described herein. This is done merely for convenience and to give a general sense of the scope of the invention. This description should be read to include one or at least one and the singular also includes the plural unless it states otherwise.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 112 (f) with respect to any of the appended claims or claim elements unless the exact words “means for” or “step for” are explicitly used in the particular claim, followed by a participle phrase identifying a function.

Benefits, other advantages, and solutions to problems have been described above with regard to specific embodiments. However, the benefits, advantages, solutions to problems, and any feature(s) that can cause any benefit, advantage, or solution to occur or become more pronounced are not to be construed as a critical, required, sacrosanct or an essential feature of any or all the claims.

After reading the specification, skilled artisans will appreciate that certain features that are, for clarity, described herein in the context of separate embodiments, can also be provided in combination in a single embodiment. Conversely, various features that are, for brevity, described in the context of a single embodiment, can also be provided separately or in any subcombination. Further, references to values stated in ranges include each and every value within that range.

What is claimed is:

1. A printed circuit board (PCB) stator for an axial field rotary energy device, the PCB stator comprising:
PCB panels, each comprising a dielectric substrate of fiber-reinforced polymer with opposite sides;
channels molded or machined in each side of each PCB panel; and
conductive wires inserted into the channels, respectively, to form conductive traces, outer surfaces of the conductive traces are substantially flush with outer surfaces of the dielectric substrate, and the conductive traces are surrounded by a resin and anchored to the dielectric substrate.

2. The PCB stator of claim 1, wherein the channels in each side of each PCB panel have a uniform depth.

3. The PCB stator of claim 2, wherein the uniform depth of the channels is equal to or greater than 140 μm.

4. The PCB stator of claim 1, wherein the conductive wires are round in sectional shape.

5. The PCB stator of claim 1, wherein the conductive wires are rectangular in sectional shape.

6. The PCB stator of claim 1, wherein the conductive wires are solid and are not stranded.

7. The PCB stator of claim 1, wherein the channels have a shape that is complementary to a shape of the conductive wires.

8. The PCB stator of claim 1, wherein each PCB panel further comprises a ground pad.

9. The PCB stator of claim 8, wherein each ground pad comprises a strip of conductive material.

10. The PCB stator of claim 8, wherein at least some of the ground pads each comprise a plurality of conductive wires.

11. The PCB stator of claim 8, wherein each ground pad comprises a thickness equal to or greater than 140 μm.

12. The PCB stator of claim 1, wherein the conductive wires are not overwrapped or taped to the PCB stator.

13. A printed circuit board (PCB) stator for an axial field rotary energy device, the PCB stator comprising:
PCB panels, each comprising a dielectric substrate of fiber-reinforced polymer with opposite sides;
channels molded or machined in each side of each PCB panel; and
the channels comprise conductive traces that are formed by inserting conductive wires in the channels, outer surfaces of the conductive wires protrude above an outer surface of the dielectric substrate, and the conductive wires are surrounded by a resin and anchored to the dielectric substrate.

14. The PCB stator of claim 13, wherein the channels in each side have a uniform depth.

15. The PCB stator of claim 14, wherein the uniform depth of the channels is equal to or greater than 140 μm.

16. The PCB stator of claim 13, wherein the conductive wires are round in sectional shape.

17. The PCB stator of claim 13, wherein the conductive wires are rectangular in sectional shape.

18. The PCB stator of claim 13, wherein the conductive wires are solid and are not stranded.

19. The PCB stator of claim 13, wherein the channels have a shape that is complementary to a shape of the conductive wires.

20. The PCB stator of claim 13, wherein each PCB panel further comprises a ground pad.

21. The PCB stator of claim 20, wherein each ground pad comprises a strip of conductive material.

22. The PCB stator of claim 20, wherein each ground pad comprises a plurality of conductive wires.

23. The PCB stator of claim 20, wherein each ground pad comprises a thickness equal to or greater than 140 μm.
